(19) United States
(12) Patent Application Publication
(10) Pub. No.: US 2022/0334147 A1
(43) Pub. Date: Oct. 20, 2022

(54) CURRENT SENSOR

(71) Applicant: Schaeffler Technologies AG & Co., KG, Herzogenaurach (DE)

(72) Inventors: Linbo Tang, Baden-Baden (DE); Thomas Lindenmayr, Nürnberg (DE); Jianwu Zhou, Shanghai (CN)

(73) Assignee: Schaeffler Technologies AG & Co., KG, Herzogenaurach (DE)

(21) Appl. No.: 17/641,590

(22) PCT Filed: Sep. 4, 2020
(86) PCT No.: PCT/DE2020/100774

§ 371 Date: Mar. 9, 2022

(30) Foreign Application Priority Data
Sep. 11, 2019 (DE) 10 2019 124 405.6

(51) Int. Cl. G01R 15/20; G01R 19/00

(52) U.S. Cl. CPC G01R 15/207; G01R 19/0092

(57) ABSTRACT

Two ferromagnetic elements are disclosed that delimit a region for an electrical conductor, in which a current intensity should be measured. Each ferromagnetic element has an end surface. The end surfaces of the two ferromagnetic elements face each other and delimit an air gap. A magnetic field sensor is arranged in the air gap or near the air gap. The region delimited by the ferromagnetic elements is open on a side opposite the air gap and can thus receive the electrical conductor. The current intensity is measured by means of a magnetic field measurement. The ferromagnetic elements can be, in particular, L-shaped.

### CROSS-REFERENCE TO RELATED APPLICATIONS

This application is the U.S. National Phase of PCT Application No. PCT/DE2020/100774, filed Sep. 4, 2020, which claims priority from German Patent Application No. 10 2019 124 405.6, filed Sep. 11, 2019, the entire disclosures of which are incorporated by reference herein.

### TECHNICAL FIELD

The disclosure relates to a current sensor for measuring the current intensity in an electrical conductor.

### BACKGROUND

Current sensors per se are widespread. One area of application among many, to which the disclosure is not intended to be restricted, is electrical drive systems, for example for motor vehicles. A current sensor can be used there, between a power electronics unit and an electrical machine or within the power electronics unit; for example, a direct current can be measured at the input of the power electronics unit or a state of a battery system can be monitored.

Known current sensors have a number of disadvantages; in particular, they are often cumbersome during assembly, both for the original installation and for replacement. Current sensors having toroidal cores are known, for example from the international patent applications WO2013/008205 A2 and WO2015/140129 A1. The electrical conductor runs through the toroidal core, so it is enclosed by the toroidal core. During assembly, the electrical conductor must be guided through the toroidal core before the electrical conductor is further installed. A change or subsequent installation of such a current sensor requires an at least partial dismantling of the electrical conductor. In another approach, known for example from the international application WO2017/130437 A1, a magnetic element is installed from one side of the electrical conductor and a sensor chip including evaluation electronics is installed from an opposite side of the electrical conductor. In this case, it is not necessary to lead the electrical conductor through the sensor, but the electrical conductor must be accessible on both sides. Furthermore, approaches are known, for example from the international applications WO2016/190087 A1 and WO2016/125638 A1, in which the current sensor already contains a piece of an electrical conductor, which, however, must then be connected with the remaining electrical conductor that forms the route in which a current intensity should be measured. Further approaches, disclosed for example in the international applications WO2017/187809 A1, WO2018/116852 A1 and WO2013/172109 A1, each use a large number of sensor elements on a carrier, some having several electrical conductors. Such approaches require several sensor elements to measure a current intensity, which causes excessive costs and is laborious to assemble.

### SUMMARY

The present disclosure provides a current sensor which does not have at least some of the aforementioned disadvantages. In particular, the current sensor should be easy to assemble and replace.

This object is achieved by a current sensor according to the present disclosure.

The current sensor according to the disclosure for measuring a current intensity in an electrical conductor comprises a magnetic field sensor to determine the current intensity by measuring a magnetic field. According to the disclosure, the current sensor has two ferromagnetic elements, each having an end face. The ferromagnetic elements are shaped and arranged in the current sensor in such a way that, on the one hand, the two end faces face each other and delimit an air gap; on the other hand, the two ferromagnetic elements together with the air gap in a plane of the current sensor delimit a region for the electrical conductor which is open on a side opposite the air gap. The electrical conductor in which a current intensity should be measured is received in this region. The mentioned plane of the current sensor is oriented in such a way that a rectilinear conductor correctly received in the current sensor runs perpendicular to this plane in the region of the current sensor. More precisely, since the region is open to one side, the current sensor can be pushed over the electrical conductor. For this purpose, neither a dismantling of the electrical conductor nor an accessibility from opposite sides is necessary; the current sensor can thus be easily installed or replaced. The two ferromagnetic elements are two separate elements between which there is no ferromagnetic connection. This is the essential aspect that enables the mentioned region to be open on one side and thus the simplified assembly. If necessary, the two ferromagnetic elements can be installed individually one after the other, but there is also the option of pre-assembling them on a carrier in the correct arrangement with respect to one another.

The two ferromagnetic elements can in particular be of the same shape. In the current sensor, the ferromagnetic elements are then arranged to be mirror-symmetrical to one another in such a way that the end surfaces which delimit the air gap face each other.

The ferromagnetic elements preferably consist of laminated cores, which reduces eddy current losses in the ferromagnetic elements.

In one embodiment, the two ferromagnetic elements are each L-shaped, each having a first leg and a second leg. The end faces delimiting the air gap are located on the second legs and the region for the electrical conductor is located between the first legs. The first legs are arranged to be parallel to one another and point in the same direction. In the plane mentioned, the L-shaped ferromagnetic elements together with the air gap delimit the region for the electrical conductor on three sides, while the region for the electrical conductor is not limited on a fourth side, which is opposite the air gap. The end faces on the second legs that face each other and delimit the air gap are preferably plane-parallel to one another, and the two L-shaped ferromagnetic elements are of the same shape. In the current sensor, the L-shaped ferromagnetic elements are then arranged to be mirror-symmetrical to one another, wherein the plane of symmetry runs in parallel to the end faces centrally through the air gap.

In general, the magnetic field sensor is arranged in the current sensor in the air gap or in the vicinity of the air gap. The magnetic field sensor is preferably arranged in one of the following positions: Within the air gap; or outside the air gap, between the air gap and a position provided for the electrical conductor; or outside the air gap, in such a way that the air gap lies between the magnetic field sensor and the region for the electrical conductor. A known measurement concept can be used for the magnetic field sensor; for example, and without restricting the disclosure thereto, it can be a sensor based on the Hall effect or a magnetoresistive effect, such as the giant magnetoresistance (GMR) effect.

In one embodiment, the magnetic field sensor is connected to a circuit board in an electrically conductive manner. Circuits on the circuit board can be provided for controlling and reading out the magnetic field sensor. The circuit board can be arranged in the current sensor in various ways, and depending on this and on the placement of the magnetic field sensor, the electrical connection, for example a number of pins, can be oriented between the magnetic field sensor and the circuit board. In principle, however, it is also conceivable to connect the magnetic field sensor directly to a higher-level system that does not belong to the current sensor for the purpose of control and reading.

In one embodiment, the two ferromagnetic elements are arranged on one plane of the circuit board and are preferably fastened to the circuit board. The circuit board has a recess for the electrical conductor.

In another embodiment, the two ferromagnetic elements are guided through the circuit board.

The current sensor can be encased in a housing. The housing can have recesses for the electrical conductor. The housing can be made in various known ways. One possibility is to form a housing made of plastic by overmolding the components of the current sensor with the plastic.

In one embodiment, the current sensor comprises an electrical conductor piece. This conductor piece is provided to form a section of the electrical conductor in which the current intensity should be measured. In a further development, the electrical conductor piece has a reduced cross-section in the region between the ferromagnetic elements. This can improve the mechanical stability of the arrangement and lead to an increase in the magnetic flux in the air gap, which improves the accuracy of the measurement.

An electrical system according to the disclosure has an electrical conductor and is characterized by a current sensor as described above for measuring a current intensity in the electrical conductor of the electrical system. The electrical conductor preferably has a reduced cross-section in the region between the ferromagnetic elements of the current sensor. The advantages of the reduced cross-section are as set out above. Here, however, the conductor or a section of the conductor in which the reduced cross-section is located does not form a component of the current sensor. The conductor section with a reduced cross-section forms an intended mounting position for the current sensor.

### BRIEF DESCRIPTION OF THE DRAWINGS

The disclosure and the advantages thereof are explained in more detail below with reference to the accompanying schematic drawings.

FIG. 1 shows an embodiment of the current sensor and a busbar.

FIG. 2 shows an embodiment of the current sensor and a busbar.

FIG. 3 shows a perspective view of a current sensor and a busbar.

FIG. 4 shows an embodiment of the current sensor and a busbar.

FIG. 5 shows an embodiment of the current sensor and a busbar.

FIG. 6 shows a perspective view of a current sensor and a busbar.

FIG. 7 shows an embodiment of the current sensor and a busbar.

FIG. 8 shows an embodiment of the current sensor and a busbar.

FIG. 9 shows a perspective view of a current sensor and a busbar.

FIG. 10 shows a perspective view of a current sensor and a busbar.

FIG. 11 shows an embodiment of a current sensor.

FIG. 12 shows an embodiment of a current sensor.

FIG. 13 shows an embodiment of the current sensor having an integrated conductor piece.

FIG. 14 shows a side view of the embodiment from FIG. 13.

FIG. 15 shows a variant of the embodiment shown in FIG. 14.

FIG. 16 shows a current sensor in connection having a higher-level circuit board.

FIG. 17 shows an embodiment of a current sensor.

FIG. 18 shows an embodiment of a current sensor.

FIG. 19 shows a perspective view of a current sensor.

FIG. 20 shows an embodiment of a current sensor.

FIG. 21 shows a current sensor in connection having a higher-level circuit board.

FIG. 22 shows three current sensors having a common circuit board.

The drawings represent only exemplary embodiments. The drawings are in no way to be interpreted as a restriction to the exemplary embodiments shown.

### DETAILED DESCRIPTION

FIG. 1 shows an embodiment of the current sensor 1 and a busbar 4 which, in this example, forms the electrical conductor in which a current intensity should be measured. The two ferromagnetic elements 2 are L-shaped and each have a first leg 21 and a second leg 22. The second leg 22 has an end face 23 in each case. The two end faces 23 face each other and thus delimit an air gap 5 in which a magnetic field sensor 3 is arranged. The first legs 21 together with the second legs 22 and the air gap 5 delimit a region 6 for the electrical conductor 4. The region 6 can be seen to be open on the side opposite the air gap 5. This precisely enables the simple assembly of the current sensor 1, as already explained. The direction of the current flow through the busbar 4 is here perpendicular to the plane of the drawing. The rectangular cross-section of the electrical conductor 4 does not constitute a restriction of the electrical conductor 4.

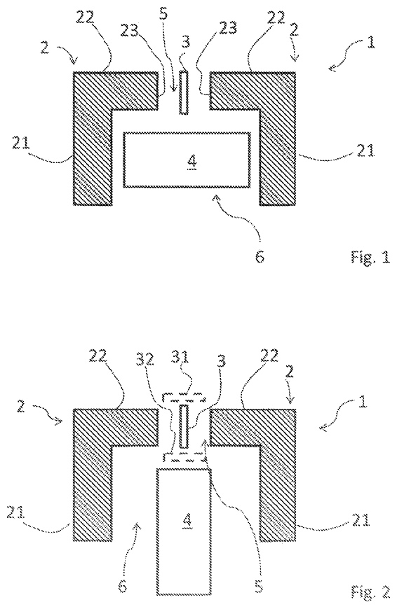

FIG. 2 shows an embodiment of the current sensor 1 and largely corresponds to the embodiment shown in FIG. 1, in which the majority of the elements shown have already been discussed. In contrast to FIG. 1, here the busbar 4 is oriented differently to the current sensor 1, and it becomes clear that the busbar 4 does not have to lie completely within the region 6 with regard to the cross-section thereof to measure a current intensity in the busbar 4. The magnetic field sensor 3 is arranged in the air gap 5. Examples of alternative positions 31, 32 for the magnetic field sensor are shown in dashed lines. For example, the magnetic field sensor can be in a position 31 outside the air gap 5 in such a way that the air gap 5 lies between the magnetic field sensor and the region 6. The magnetic field sensor can, however, also lie in a position 32 within the region 6, between the air gap 5 and the busbar 4. These alternative positions 31, 32 for the magnetic field sensor are of course also possible with an arrangement of the busbar 4 as in FIG. 1.

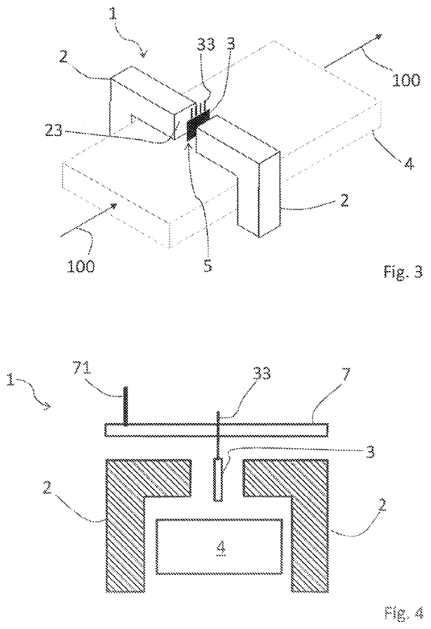

FIG. 3 shows a perspective view of a current sensor 1 and a busbar 4. The direction 100 of a current flow through the busbar 4 is shown. In the case of the ferromagnetic elements 2, one of the end faces 23 can be seen; a magnetic field sensor 3, for which connection pins 33 are shown, is arranged in the air gap 5.

FIG. 4 shows a current sensor 1 and a busbar 4; some of the elements shown have already been discussed with reference to FIG. 1. One of the connection pins 33 for the magnetic field sensor 3 is shown, which connects the magnetic field sensor 3 to a circuit board 7 for controlling and reading out the magnetic field sensor 3. The circuit board 7 has one or more connection pins 71 for connection to a higher-level system.

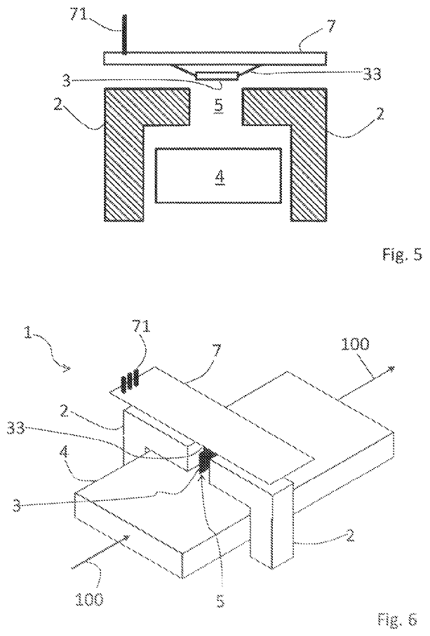

FIG. 5 shows a current sensor 1 and a busbar 4, analogous to FIG. 4. In contrast to the embodiment shown in FIG. 4, the magnetic field sensor 3 is arranged outside the air gap 5.

FIG. 6 shows a perspective view of a current sensor 1 and a busbar 4. The direction 100 of a current flow through the busbar 4 is shown. A magnetic field sensor 3, which is connected to a circuit board 7 via connection pins 33, is arranged in the air gap 5 between the ferromagnetic elements 2. The circuit board 7 is used to control and read out the magnetic field sensor 3 and has connection pins 71 for connecting the circuit board 7 to a higher-level system.

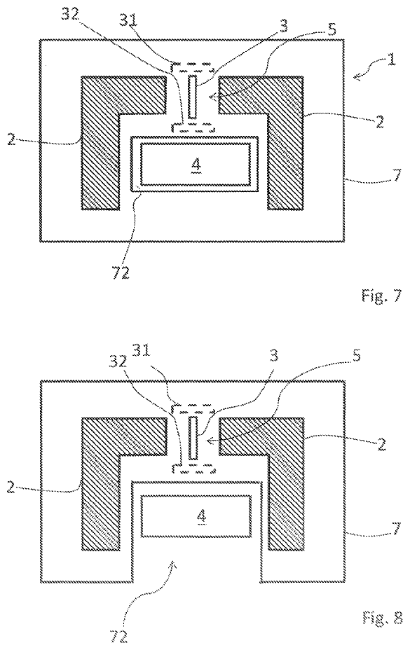

FIG. 7 shows a current sensor 1 with ferromagnetic elements 2 and a magnetic field sensor 3 which is arranged in the air gap 5 between the ferromagnetic elements 2. Examples of alternative positions 31, 32 for the magnetic field sensor 3 are also indicated by dashed lines. A circuit board 7 for controlling and reading out the magnetic field sensor 3 belongs to the current sensor 1. The ferromagnetic elements 2 are arranged here on a plane of the circuit board 7. A recess 72 is provided in the circuit board 7 for the busbar 4 in which a current intensity should be measured. In this exemplary embodiment, when the current sensor 1 is installed, the busbar 4 must be guided through the cutout 72.

FIG. 8 is an embodiment of a current sensor 1, largely analogous to the embodiment shown in FIG. 7; in FIG. 7 the elements shown have already been explained. In contrast to the embodiment shown in FIG. 7, the recess 72 for the busbar 4 in the circuit board 7 is designed so that the current sensor 1 can be plugged over the busbar 1, which simplifies the assembly compared to the embodiment of FIG. 7.

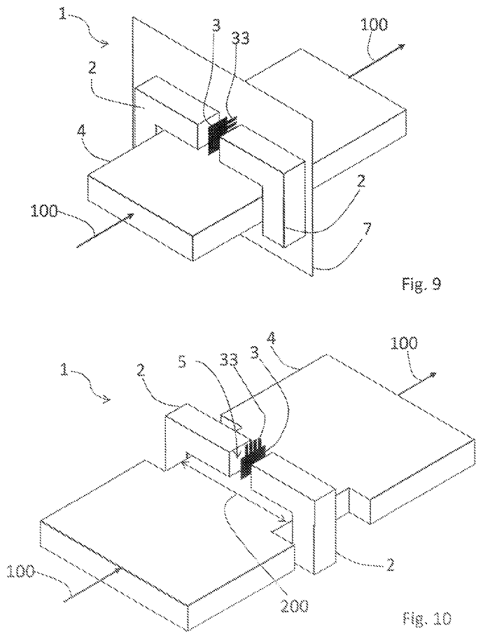

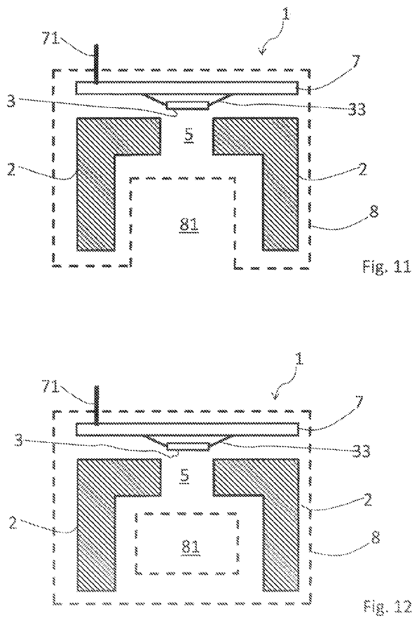

FIG. 9 is a perspective view of the embodiment shown in FIG. 7. The elements shown have already been explained in connection with FIG. 7. The direction 100 of the current flow is indicated for the busbar 4. For the magnetic field sensor 3, the connection pins 33 for connection to the circuit board 7 are also shown.

FIG. 10 shows a perspective view of a further embodiment of a current sensor 1 and a busbar 4, for which the direction 100 of the current flow is shown. In the air gap 5 between the ferromagnetic elements 2 is arranged the magnetic field sensor 3, for which connection pins 33 for connecting to a circuit board are shown. The busbar 4 has a reduced cross-section 200 in the region of the current sensor 1.

FIG. 11 shows an embodiment of a current sensor 1, which is a variant of the embodiment shown in FIG. 5. Most of the elements shown have already been explained in FIG. 5. The components of the current sensor 1 are surrounded here by a housing 8 (shown in dashed lines), only the connection pins 71 for connecting the circuit board 7 to a higher-level system are accessible from outside the housing 8. The housing 8 is designed in such a way that a recess 81 results in which can be received an electrical conductor in which the current intensity should be measured. In the exemplary embodiment shown, the recess is such that the current sensor 1 can be pushed over the electrical conductor.

FIG. 12 shows a modification of the embodiment shown in FIG. 11. All the elements shown have already been explained with reference to FIG. 11. In contrast to the embodiment shown in FIG. 11, the recess 81 in the housing 8 does not allow the subsequent sliding of the current sensor 1 onto an electrical conductor, rather the electrical conductor must be guided through recess 81 during assembly.

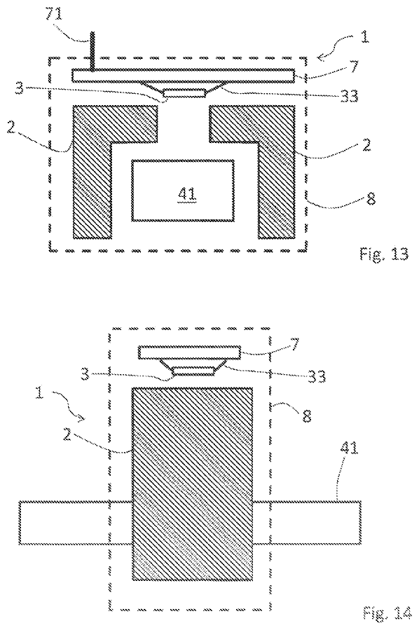

FIG. 13 shows an embodiment of a current sensor 1, which comprises an integrated conductor piece 41. Also shown are the ferromagnetic elements 2, magnetic field sensor 3 having connection pins 33 to a circuit board 7, which is used to control and read out the magnetic field sensor 3, and a connection pin 71 for connecting the circuit board 7 to a higher-level system. The current sensor 1 also has a housing 8 (shown in dashed lines). The integrated conductor piece 41 can also have a reduced cross-section in the region of the ferromagnetic elements 2, analogous to the illustration in FIG. 10 for a busbar 4 that does not belong to the current sensor 1.

FIG. 14 shows a side view of the embodiment shown in FIG. 13. The elements shown have already been explained in connection with FIG. 13. As can be seen, the electrical conductor piece 41 protrudes from the housing 8. The electrical conductor piece 41 can be connected to an electrical conductor on both sides to form a conductor path in which a current intensity should be measured.

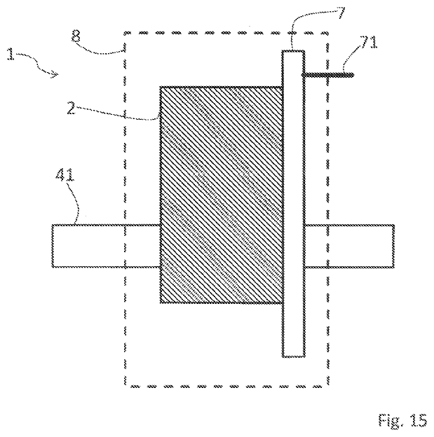

FIG. 15 shows a side view of a variant of the embodiment shown in FIG. 14. The difference from the embodiment shown in FIG. 14 lies in the arrangement of the circuit board 7 relative to the ferromagnetic elements 2. This arrangement corresponds to the embodiment shown in FIG. 9.

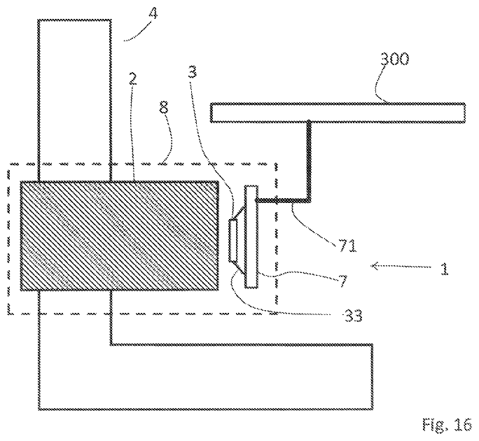

FIG. 16 shows a current sensor 1 having a housing 8, which corresponds approximately to the embodiment shown in FIG. 11 or FIG. 12. The illustrated elements of the current sensor 1 have already been explained in relation to these figures. The circuit board 7 is connected to a higher-level circuit board 300 via connection pin 71. The busbar 4, in which a current intensity should be measured, is shown here with an angled profile. The arrangement of the higher-level circuit board 300 relative to the current sensor 1 and busbar 4 is of course only an example.

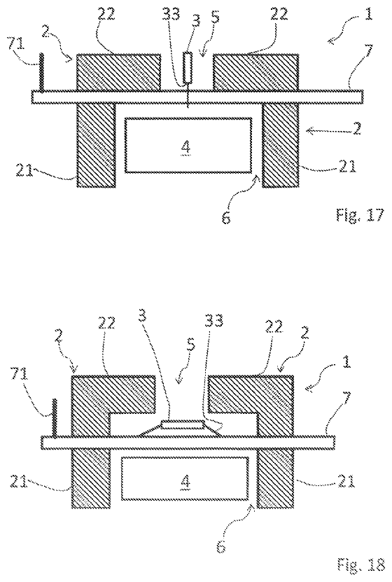

FIG. 17 shows an embodiment of a current sensor 1 having a magnetic field sensor 3 in the air gap 5 between the second legs 22 of the ferromagnetic elements 2. The magnetic field sensor 3 is connected via connection pins 33 to the circuit board 7, which has a connection pin 71 for connection to a higher-level system and is designed to control and read out the magnetic field sensor 3. A busbar 4 is received in the region 6 between the first legs 21 of the ferromagnetic elements 2. In the embodiment shown, the ferromagnetic elements 2 penetrate the circuit board 7, more precisely the second legs 22 rest on the circuit board 7, and the first legs 21 run through the circuit board 7 and extend on the side of the circuit board 7 opposite the second legs 22.

FIG. 18 shows a variant of the embodiment shown in FIG. 17. The elements shown have already been explained in connection with FIG. 17. In contrast to the embodiment in FIG. 17, the magnetic field sensor 3 is arranged outside the air gap 5; in addition, the second legs 22 are spaced apart from the circuit board 7.

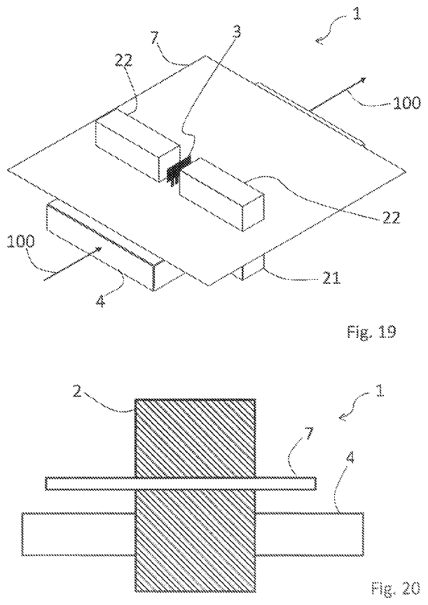

FIG. 19 shows a perspective view of the embodiment shown in FIG. 17. The elements shown have largely already been explained with reference to FIG. 17. The direction 100 of a current flow through the busbar 4 is also shown.

FIG. 20 shows a side view of the embodiment shown in FIG. 17. The elements shown have already been explained in connection with FIG. 17.

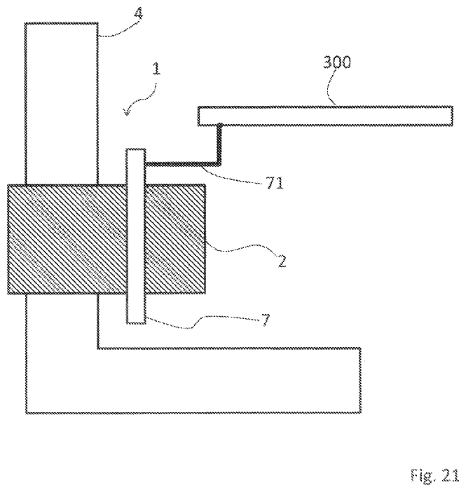

FIG. 21 shows an embodiment of a current sensor 1, corresponding approximately to the embodiment shown in FIG. 17. The ferromagnetic elements 2 penetrate the circuit board 7, which is used to control and read out the magnetic field sensor 3 (see FIG. 17) and is connected to a higher-level circuit board 300 via connection pin 71. The current sensor 1 is shown here for measuring a current intensity in a busbar 4 having an angled profile. The arrangement of the higher-level circuit board 300 relative to the current sensor 1 and busbar 4 is of course only an example.

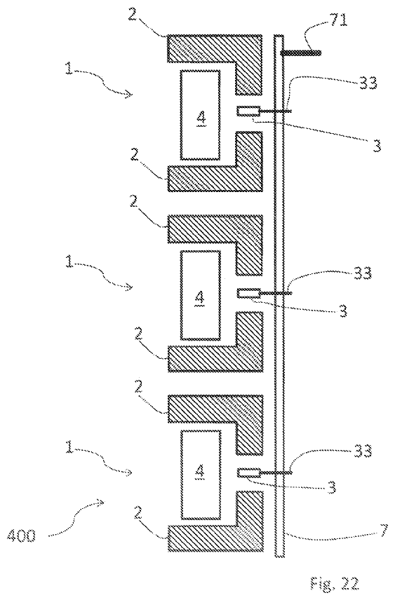

FIG. 22 shows an arrangement 400 of three current sensors 1, each of which here corresponds approximately to the embodiment shown in FIG. 3. Each current sensor 1 has two L-shaped ferromagnetic elements 2, between which a busbar 4 is shown here, in which a current intensity should be measured with the respective current sensor 1. Each current sensor 1 has a magnetic field sensor 3 which is arranged in the air gap between the respective ferromagnetic elements 2. Each magnetic field sensor 3 is connected to a circuit board 7 common to the three current sensors 1 shown via a respective connection pin 33. The circuit board 7 is used to control and read out the three magnetic field sensors 3. The circuit board 7 has a connection pin 71 for connection to a higher-level system. An arrangement as shown here, for example, can be used to measure the currents in the individual phases of a multi-phase, specifically three-phase, electrical system.

### LIST OF REFERENCE SYMBOLS

a. Current sensor
b. Ferromagnetic element
c. Magnetic field sensor
d. Busbar (electrical conductor)
e. Air gap
f. Region (for electrical conductors)
g. Circuit board (current sensor)
h. Housing
21 First leg
22 Second leg
23 End surface
31 Magnetic field sensor (alternative position)
32 Magnetic field sensor (alternative position)
33 Connection pin (magnetic field sensor)
41 Electrical conductor piece
71 Connection pin (circuit board)
72 Recess (in circuit board)
81 Recess (in housing)
100 Direction (current flow)
200 Reduced cross-section (busbar)
300 Higher-level circuit board
400 Arrangement

1. A current sensor for measuring a current intensity in an electrical conductor, the current sensor comprising:
a magnetic field sensor,
two ferromagnetic elements, each having an end surface which is shaped and arranged in such a way that the two end surfaces face each other and delimit an air gap, and the two ferromagnetic elements, together with the air gap, in a plane of the current sensor, delimit a region for the electrical conductor which is open on a side opposite the air gap.

2. The current sensor according to claim 1, wherein the two ferromagnetic elements are each designed to be L-shaped, having a first leg and a second leg, the end surfaces delimiting the air gap on the second legs and the region for the electrical conductor between the first legs.

3. The current sensor according to claim 1, wherein the magnetic field sensor is arranged in one of the following positions:
within the air gap; or
outside the air gap, between the air gap and a position provided for the electrical conductor; or
outside the air gap so that the air gap lies between the magnetic field sensor and the region for the electrical conductor.

4. The current sensor according to claim 1, wherein the magnetic field sensor is connected in an electrically conductive manner to a circuit board.

5. The current sensor according to claim 4, wherein the two ferromagnetic elements are arranged on one plane of the circuit board and the circuit board has a recess for the electrical conductor.

6. The current sensor according to claim 4, wherein the two ferromagnetic elements are guided through the circuit board.

7. The current sensor according to claim 1, wherein the current sensor is encased in a housing.

8. The current sensor according to claim 1, wherein the current sensor comprises an electrical conductor piece which is provided to form a section of the electrical conductor.

9. The current sensor according to claim 8, wherein the electrical conductor piece has a reduced cross-section in the region between the ferromagnetic elements.

10. An electrical system having an electrical conductor, comprising the current sensor according to claim 1 for measuring a current intensity in the electrical conductor of the electrical system, wherein the electrical conductor in the region between the ferromagnetic elements of the current sensor has a reduced cross-section.

11. A current sensor for measuring a current intensity in an electrical conductor, the current sensor comprising:
a magnetic field sensor, and
two ferromagnetic elements each having an L-shaped profile with a first leg and a second leg, wherein the first legs of the two ferromagnetic elements extend parallel to each other and the second legs of the two ferromagnetic elements extend towards each other and define an air gap therebetween,
wherein a region dimensioned to receive a portion of the electrical conductor is defined by the two ferromagnetic elements, and the region is connected to the air gap.

12. The current sensor according to claim 11, wherein the magnetic field sensor is arranged in one of the following positions:
within the air gap; or
outside the air gap, between the air gap and a position provided for the electrical conductor; or
outside the air gap so that the air gap lies between the magnetic field sensor and the region for the electrical conductor.

13. The current sensor according to claim 11, wherein the magnetic field sensor is connected in an electrically conductive manner to a circuit board.

14. The current sensor according to claim 13, wherein the two ferromagnetic elements are arranged on one plane of the circuit board and the circuit board has a recess for the electrical conductor.

15. The current sensor according to claim 13, wherein the two ferromagnetic elements are guided through the circuit board.

16. The current sensor according to claim 11, wherein the current sensor is encased in a housing.

17. The current sensor according to claim 11, wherein the current sensor comprises an electrical conductor piece which is forms a section of the electrical conductor.

18. The current sensor according to claim 17, wherein the electrical conductor piece has a reduced cross-section in the region between the ferromagnetic elements.
